(19) United States
(12) Patent Application Publication
(10) Pub. No.: US 2016/0126480 A1
(43) Pub. Date: May 5, 2016

(54) Metal Complexes

(71) Applicant: MERCK PATENT GMBH, Darmstadt (DE)

(72) Inventors: Lars Wesemann, Tuebingen (DE); Matthias Kleith, Denkendorf (DE); Hermann August Mayer, Tuebingen (DE)

(73) Assignee: Merck Patent GmbH, Darmstadt (DE)

(21) Appl. No.: 14/776,796

(22) PCT Filed: Feb. 24, 2014
(86) PCT No.: PCT/EP2014/000480

§ 371 Date: Jan. 4, 2016

(30) Foreign Application Priority Data
Mar. 16, 2013 (EP) 13001354.3

(51) Int. Cl. H01L 51/00; C09K 11/06; C07F 19/00

(52) U.S. Cl. CPC H01L 51/0091; C07F 19/005; C09K 11/06; H01L 51/5016

(57) ABSTRACT

The present invention relates to metal complexes in accordance with formula (1), to use thereof in electronic devices and to electronic devices, particularly organic electroluminescent devices, containing said metal complexes.

The present application relates to metal complexes, to the use of these metal complexes in electronic devices, and to electronic devices, especially organic electroluminescent devices, comprising these metal complexes.

The structure of organic electroluminescent devices (OLEDs) in which organic semiconductors are used as functional materials is described, for example, in U.S. Pat. No. 4,539,507, U.S. Pat. No. 5,151,629, EP 0878461 and WO 98/27136. These are increasingly using organometallic complexes which exhibit phosphorescence rather than fluorescence as emitting materials (M. A. Baldo et al., Appl. Phys. Lett, 1999, 75, 4-6). For quantum-mechanical reasons, up to four times the energy efficiency and power efficiency is possible using organometallic compounds as phosphorescent emitters. There is generally always a need for improvement in OLEDs which exhibit triplet emission. Thus, the physical properties of phosphorescent OLEDs, in terms of efficiency, operating voltage and lifetime, are still not sufficient for the use of triplet emitters in high-value and long-lived electroluminescent devices. This is especially true of OLEDs which emit in the shorter-wave range, i.e. green and especially blue.

According to the prior art, triplet emitters used in phosphorescent OLEDs are usually indium complexes and platinum complexes. However, these have the disadvantage that they are scarce metals and therefore also correspondingly costly metals. To preserve the natural resources of these metals, it would therefore be desirable to have available emitters based on other metals. A further disadvantage of the iridium complexes and platinum complexes typically used is that they are usually organometallic complexes having metal-carbon bonds. Some of these metal-carbon bonds can be obtained synthetically only with difficulty. Moreover, some of these complexes have only low thermal stability.

In the case of matrix materials too, for example materials based on zinc complexes, or electron conductors, for example based on aluminum complexes, further improvements are still desirable.

It is therefore an object of the present invention to provide metal complexes which are suitable as emitters, as matrix materials, as electron conductors or in other functions for use in OLEDs, which have a high thermal stability, which lead to high efficiencies and/or high lifetimes when used in OLEDs and/or which are easily obtainable synthetically.

It has been found that, surprisingly, particular metal chelate complexes described below achieve this object and are of very good suitability for use in organic electroluminescent devices, especially when used as emitting material. At the same time, they exhibit a high lifetime, high efficiency and/or good stability with respect to thermal stress. Moreover, the central atom of these complexes is not iridium or platinum, which are scarce metals. A further advantage of these complexes is that they are easily obtainable synthetically. The present invention therefore provides these complexes and electronic devices, especially organic electroluminescent devices, containing these complexes.

The present invention thus provides a compound of the following formula (1)

where the symbols and indices used are as follows:
M is selected from Cu, Ag, Au, Zn and Al;
A is selected from N and P;
Y is the same or different at each instance and is a bivalent group selected from CR₂, O, S, 1,2-vinylene, 1,2- or 1,3-phenylene and an ortho-bonded heteroarylene group having 5 or 6 aromatic ring atoms, where each of these groups may be substituted by one or more R radicals;
L¹, L², L³ is the same or different at each instance and is a heteroaryl group which has 5 to 25 aromatic ring atoms and may be substituted by one or more R radicals and which contains a nitrogen, sulfur or oxygen atom which may coordinate to M, or an aryl or heteroaryl group which has 5 to 18 aromatic ring atoms and may be substituted by one or more R radicals and which has an exocyclic donor atom selected from N, O, S and P which coordinates to M and which may be substituted by one or more R radicals;
n is the same or different at each instance and is 0, 1, 2, 3, 4 or 5;
R is the same or different at each instance and is H, D, F, Cl, Br, I, N(R¹)₂, CN, NO₂, OR¹, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms or a branched or cyclic alkyl, alkoxy or thioalkoxy group having 3 to 40 carbon atoms or an alkenyl or alkynyl group having 2 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more hydrogen atoms may be replaced by F, Cl, Br, I, CN or NO₂, or an aromatic or heteroaromatic ring system which has 5 to 60 aromatic ring atoms, each of which may be substituted by one or more R¹ radicals, or an aryloxy, heteroaryloxy, aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; two or more R substituents together may also form a mono- or polycyclic, aliphatic, aromatic, heteroaromatic and/or benzofused ring system;
R¹ is the same or different at each instance and is H, D, F, Cl, Br, I, N(R²)₂, CN, NO₂, OH, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 40 carbon atoms or a branched or cyclic alkyl, alkoxy or thioalkoxy group having 3 to 40 carbon atoms or an alkenyl or alkynyl group having 2 to 40 carbon atoms, each of which may be substituted by one or more R² radicals, where one or more nonadjacent CH₂ groups may be replaced by R²C═CR², C≡C, Si(R²)₂, C═O, C═S, C═NR², P(═O)(R²), SO, SO₂, NR², O, S or CONR² and where one or more hydrogen atoms may be replaced by F, Cl, Br, I, CN or NO₂, or an aromatic or heteroaromatic ring system which has 5 to 60 aromatic ring atoms, each of which may be substituted by one or more R² radicals, or an aryloxy, heteroaryloxy, aralkyl or heteroaralkyl group which has 5 to 60 aromatic ring atoms and may be substituted by one or more R² radicals, or a diarylamino group, diheteroarylamino group or arylheteroarylamino group which has 10 to 40 aromatic ring atoms and may be substituted by one or more R² radicals; two or more R¹ substituents together may also form a mono- or polycyclic, aliphatic, aromatic, heteroaromatic and/or benzofused ring system;
R² is the same or different at each instance and is H, D, F or an aliphatic, aromatic and/or heteroaromatic hydrocarbyl radical having 1 to 20 carbon atoms, in which one or more hydrogen atoms may also be replaced by F; two or more R² substituents together may also form a mono- or polycyclic, aliphatic, aromatic, heteroaromatic and/or benzofused ring system.

The compound of the formula (1), if it is a charged compound, also contains one or more counterions which may be the same or different.

The ligand L coordinates to the metal M via the free electron pair of the bridgehead A and via the partial ligands L¹, L² and L³. A partial ligand in the context of the present invention, in the ligand of the formula (2), is understood to mean the L¹, L² and L³ groups which each coordinate to the metal M and are joined to one another via A and optionally via Y. These partial ligands L¹, L² and L³ may coordinate to M via an uncharged or negatively charged donor atom, where this donor atom may either be part of the heteroaryl group or may be bonded to an aryl or heteroaryl group in an exocyclic position.

A donor atom in the context of the present invention is understood to mean an atom which has at least one free electron pair and is thus capable of binding to a metal ion. The donor atom may be uncharged or negatively charged. Examples of donor atoms which are part of a heteroaryl group are nitrogen in pyrrole, indole or pyridine, oxygen in furan or benzofuran, and sulfur in thiophene or benzothiophene.

An exocyclic donor atom in the context of this invention is understood to mean a donor atom which is not part of an aryl or heteroaryl group but which is bonded as a substituent to an aryl or heteroaryl group and which has at least one free electron pair and is thus capable of binding to a metal ion. The donor atom may be uncharged or negatively charged. Examples of exocyclic donor atoms are oxygen in the form of a phenol or phenoxide, sulfur in the form of a thiol or thiolate, nitrogen in the form of an amine, imine, amide or imide, and phosphorus in the form of a phosphine.

An aryl group in the context of this invention contains 6 to 60 carbon atoms; a heteroaryl group in the context of this invention contains 2 to 60 carbon atoms and at least one heteroatom, with the proviso that the sum of carbon atoms and heteroatoms is at least 5. The heteroatoms are preferably selected from N, O and/or S. An aryl group or heteroaryl group is understood here to mean a simple aromatic cycle, i.e. benzene, or a simple heteroaromatic cycle, for example pyridine, pyrimidine, thiophene, etc., or a fused aryl or heteroaryl group, for example naphthalene, anthracene, phenanthrene, quinoline, isoquinoline, etc. A cyclic carbene in the context of this invention is a cyclic group which binds to the metal via an uncharged carbon atom. The cyclic group may be saturated or unsaturated. Preference is given here to Arduengo carbenes, i.e. those carbenes in which two nitrogen atoms are bonded to the carbene carbon atom.

An aromatic ring system in the context of this invention contains 6 to 60 carbon atoms in the ring system. A heteroaromatic ring system in the context of this invention contains 2 to 60 carbon atoms and at least one heteroatom in the ring system, with the proviso that the sum of carbon atoms and heteroatoms is at least 5. The heteroatoms are preferably selected from N, O and/or S. An aromatic or heteroaromatic ring system in the context of this invention is understood to mean a system which does not necessarily contain only aryl or heteroaryl groups, but in which it is also possible for two or more aryl or heteroaryl groups to be interrupted by a nonaromatic unit (preferably less than 10% of the atoms other than H), for example an sp³-hybridized carbon, nitrogen or oxygen atom. For example, systems such as 9,9′-spirobifluorene, 9,9′-diaryffluorene, triarylamine, diaryl ethers, stilbene, etc. are also to be regarded as aromatic ring systems in the context of this invention, and likewise systems in which two or more aryl groups are interrupted, for example, by a linear or cyclic alkyl group or by a silyl group.

In the context of the present invention, a C₁- to C₄₀-alkyl group in which individual hydrogen atoms or CH₂ groups may be replaced by the abovementioned groups are preferably understood to mean the methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl and 2,2,2-trifluoroethyl radicals. An alkenyl group is preferably understood to mean the ethenyl, propenyl, butenyl, pentenyl, cyclopentenyl, hexenyl, cyclohexenyl, heptenyl, cycloheptenyl, octenyl and cyclooctenyl radicals. An alkynyl group is preferably understood to mean ethynyl, propynyl, butynyl, pentynyl, hexynyl, heptynyl and octynyl. A C₁- to C₄₀-alkoxy group is preferably understood to mean methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system which has 5-60 aromatic ring atoms and may also be substituted in each case by R radicals as defined above and which may be joined to the aromatic or heteroaromatic system via any desired positions is especially understood to mean groups derived from benzene, naphthalene, anthracene, phenanthrene, benzanthracene, benzophenanthrene, pyrene, chrysene, perylene, fluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The partial ligands L¹, L² and L³ may also be joined to one another via R radicals which form bridges to one another. This results in cryptates formed from the complex of the formula (1) having a polypodal ligand. A polypodal ligand in the context of this invention is understood to mean a ligand in which three coordinating partial ligands L¹, L² and L³ are joined to one another by an A group. The ligand in the compound of the formula (1) is therefore a polypodal ligand. A cryptate in the context of this invention is understood to mean a compound between a cryptand and a metal ion in which the metal ion is three-dimensionally surrounded by the bridges of the complex-forming cryptand. A cryptand in the context of this invention is understood to mean a macrocyclic tripodal ligand. A cryptand can form when all three of the partial ligands L¹, L² and L³ or when two of the three partial ligands are joined to one another via R radicals. This is shown in schematic form hereinafter:

where R in this structure represents the formation of rings by R radicals in the partial ligands L¹, L² and L³ and the further symbols and indices used are each as defined above. In this context, R is as defined above, but the group is a bivalent or trivalent group, and so the corresponding monovalent groups such as halogens are not an option.

In a preferred embodiment of the invention, M is selected from the group consisting of Cu(I), Ag(I), Au(I), Zn(II) and Al(III). Particular preference is given to Cu(I). The value in brackets after the metal means the oxidation state of the metal in each case. These metals have tetrahedral coordination or at least approximately tetrahedral or distorted tetrahedral coordination.

When the compound of the formula (1) has an electrical charge, it also contains one or more counterions which may be the same or different.

When the compound of the formula (1) has a positive charge, the counterion is preferably selected from the group consisting of BF₄⁻, PF₆⁻, F⁻, Cl⁻, Br⁻, I⁻, NO₃⁻, CuCl₂⁻, CuBr₂⁻, CuI₂⁻, B(aryl)₄⁻, B(alkyl)₄⁻, HSO₄⁻, SO₄²⁻, PO₄³⁻, HCO₃⁻, CO₃²⁻, BO₃³⁻, OCN⁻, SCN⁻, CN⁻, CF₃SO₃⁻ and SbFe₆⁻. When the compound of the formula (1) is negatively charged, the counterion is preferably selected from the group consisting of Li⁺, Na⁺, K⁺, Mg²⁺, Ca²⁺, Sr²⁺, Ba²⁺, NH₄⁺, N(aryl)₄⁺, N(alkyl)₄⁺, P(aryl)₄⁺, P(alkyl)₄⁺, P[N(CH₃)₂]₄⁺, S[N(CHS)₂]₃⁺ and [C₁₁H₂₄N]⁺ (hexamethylpiperidinium), where the alkyl group in each case is the same or different at each instance and preferably has 1 to 10 carbon atoms and aryl in each case is the same or different at each instance and is an aryl or heteroaryl group having 5 to 10 aromatic ring atoms.

In a preferred embodiment of the invention, the compound of the formula (1) has no electrical charge. This is achieved by virtue of the charges of partial ligands L¹, L² and L³ being chosen so as to compensate for the charge of M. When M is Cu(I), Ag(I) or Au(I), it is thus preferable for one of partial ligands L¹, L² and L³ to coordinate via a negatively charged donor atom and the other partial ligands to coordinate via uncharged donor atoms. When M is Zn(II), it is preferable for two of partial ligands L¹, L² and L³ to coordinate via negatively charged donor atoms and the third partial ligand to coordinate via an uncharged donor atom. When M is Al(III), it is preferable for all three partial ligands L¹, L² and L³ to coordinate via negatively charged donor atoms.

In a preferred embodiment of the invention, the cycle which is formed from A, Y, M and L¹ and/or L² and/or L³ preferably contains 5, 6, 7, 8 or 9 ring atoms. Depending on the exact structure of partial ligands L¹, L² or L³, the index n is correspondingly chosen such that the coordination of M gives rise to a 5-, 6-, 7-, 8- or 9-membered ring. What is meant by the formation of a 5-, 6-, 7-, 8- or 9-membered ring is shown in schematic form hereinafter using some partial structures:

In each case, the structure containing one arm of the polypodal ligand and a partial ligand is depicted. In all the structures depicted, the partial ligand is pyridine and Y is CH₂. For the 5-membered ring n=1, for the 6-membered ring n=2, etc. In the case of a different choice of partial ligands, it is also possible, for example, with n=0 to form a 5-membered ring, or with n=0 or 1 to form a six-membered ring, as shown schematically hereinafter:

In the first structure the partial ligand is quinoline and n=0, in the second structure the partial ligand is quinoline, n=1 and Y═CH₂, and in the third structure the partial ligand is phenanthridine and n=0.

More preferably, the cycle which is formed from A, Y, M and L¹ and/or L² and/or L³ contains 6, 7, 8 or 9 ring atoms, more preferably 6, 7 or 8 ring atoms. Which combinations of ring sizes are preferred for the individual partial ligands L¹ and/or L² and/or L³ depends on the nature of Y. When Y is an aromatic group or when n=0 and the partial ligand L¹ and/or L² and/or L³ binds directly to A, preferred ring sizes are (6-6-6), (5-6-7), (6-6-7), (6-7-7) and (7-7-7). Each of these three numbers indicates the ring size that the corresponding “arm” of the polypodal ligand forms with the metal atom. For example, (5-6-7) means that the cycle which is formed from A, Y, M and L¹ has 5 ring atoms and the cycle which is formed from A, Y, M and L² has 6 ring atoms and the cycle which is formed from A, Y, M and L³ has 7 ring atoms. When Y is aliphatic, the individual arms of the polypodal ligand are not planar and, as a result, are somewhat shortened as compared with purely aromatic arms, and so the ring sizes (6-6-6) here lead only to a distorted tetrahedron and larger rings are advantageous, especially the combination of 6-membered with 7- and/or 8-membered rings or combinations of 7- and/or 8-membered rings.

In a preferred embodiment of the invention, L¹ or L² or L³ has 5 to 14 aromatic ring atoms, more preferably 5 to 13 aromatic ring atoms, most preferably 5 to 10 aromatic ring atoms. The aryl or heteroaryl groups may be substituted by one or more R radicals, as described above.

In a preferred embodiment of the invention, L¹, L² and L³ are the same or different at each instance and are selected from the groups of the formulae (2) to (41):

where R has the same definition as described above and in addition:
X is the same or different at each instance and is CR or N;
D is the same or different at each instance and is OH, O⁻, SH, S⁻, NR₂, NR⁻, PR⁻, PR₂, OR, SR, COO⁻, —C(═O)R, —CR(═NR) or —N(═CR₂).

Among these structures, preference is given to the groups of the formulae (2), (7), (9), (10), (12), (13), (15), (33), (34), (37), (39), (40) and (41) and particular preference to the groups of the formulae (9), (12), (33), (34), (39), (40) and (41).

The groups of the formulae (2) to (41) coordinate to the metal M via the position identified by *. The position identified by # indicates the position where the partial ligand L¹ or L² or L³ is bonded to Y or to A.

Preferably not more than three X symbols in each group are N, more preferably not more than two X symbols in each group are N, and even more preferably not more than one X symbol in each group is N. Especially preferably, all X symbols are CR.

In a further preferred embodiment of the invention, Y is the same or different at each instance and is a bivalent group selected from CR₂ and O, more preferably CR₂. If A=N, Y is preferably not O.

In a further preferred embodiment of the invention, the index n is the same or different at each instance and is 0, 1 or 2.

Preferred structures of formula (1) are structures in which the abovementioned preferences occur simultaneously, i.e. structures in which:
L¹, L², L³ is the same or different at each instance and is selected from the abovementioned groups of the formulae (2) to (41), where not more than three X symbols in each group are N;
Y is the same or different at each instance and is a bivalent group selected from CR₂ and O;
n is the same or different at each instance and is 0, 1 or 2.

Particularly preferred structures of formula (1) are structures in which:
L¹, L², L³ is the same or different at each instance and is selected from the abovementioned groups of the formulae (2), (7), (9), (10), (12), (13), (15), (33), (34), (37), (39), (40) and (41), where not more than two X symbols, preferably not more than one X symbol, in each group are N;
Y is the same or different at each instance and is CR₂;
n is the same or different at each instance and is 0 or 1.

The further symbols and indices used are each as defined above.

Preference is further given to compounds of formula (1) or according to the preferred embodiments detailed above in which R is the same or different at each instance and is H, D, F, CN, a straight-chain alkyl or alkoxy group having 1 to 10 carbon atoms or a branched or cyclic alkyl or alkoxy group having 3 to 10 carbon atoms, each of which may be substituted by one or more R¹ radicals, where one or more nonadjacent CH₂ groups may be replaced by R¹C═CR¹, O or S and one or more hydrogen atoms may be replaced by D or F, or an aromatic or heteroaromatic ring system having 5 to 18 aromatic ring atoms, each of which may be substituted by one or more R¹ radicals, or a diarylamino group which has 10 to 20 aromatic ring atoms and may be substituted by one or more R¹ radicals, or a combination of these systems; two or more R substituents together may also form a mono- or polycyclic aliphatic, aromatic and/or benzofused ring system. More preferably, the symbol R in these compounds is the same or different at each instance and is H, D, F, a straight-chain alkyl group having 1 to 6 carbon atoms or a branched alkyl group having 3 to 6 carbon atoms, each of which may be substituted by one or more R¹ radicals, where one or more hydrogen atoms may be replaced by F, or an aryl group having 6 to 10 aromatic ring atoms or an aromatic ring system having 12 to 18 aromatic ring atoms, each of which may be substituted by one or more R¹ radicals; two or more R substituents together may also form a mono- or polycydic aliphatic, aromatic and/or benzofused ring system.

Preference is further given to compounds in which at least two of the partial ligands L¹, L² and L³ are the same and also have the same substitution.

Examples of suitable ligands which coordinate to M as uncharged or monoanionic ligands are the ligands listed hereinafter, each of which is present in deprotonated form in the case of coordination as monoanionic ligands.

Examples of suitable ligands which coordinate to M as uncharged, monoanionic or dianionic ligands are the ligands listed hereinafter, each of which is present in monodeprotonated form in the case of coordination as monoanionic ligands and each of which is present in fully deprotonated form in the case of coordination as dianionic ligands.

Examples of suitable ligands which coordinate to M as uncharged, monoanionic, dianionic or trianionic ligands are the ligands listed hereinafter, each of which is present in monodeprotonated form in the case of coordination as monoanionic ligands, each of which is present in dideprotonated form in the case of coordination as dianionic ligands, and each of which is present in fully deprotonated form in the case of coordination as trianionic ligands.

As described above, for the metal complexes, preference is given in each case to choosing a ligand which compensates for the charge of the metal atom, i.e. a monoanionic ligand for Cu, Ag and Au, a dianionic ligand for Zn and a trianionic ligand for Al. A in the above-listed structures is N or P. The aromatic systems indicated by dotted bonds may be present or else absent independently of one another, but only when they form a complete aromatic group. In addition, individual carbon atoms in the above-listed ligands may also be replaced by N. In addition, the structures may be substituted by one or more R radicals, where R has the definitions given above. In the ligands depicted above, in the interests of clarity, these are named with a three-figure number. Each of these three numbers indicates the ring size that the corresponding “arm” of the polypodal ligand forms with the metal atom.

Examples of inventive compounds of formula (1) are the compounds detected hereinafter.

The synthesis of the ligands can in principle be conducted analogously for all the ligands, with synthesis of a tertiary amine or phosphine in each case. This can be effected in various ways.

One option is the triple amination of ammonia, as shown in Scheme 1 below in general terms for the synthesis of a tertiary amine having two different arms.

For this purpose, mono-protected ammonia is reacted with two equivalents of an aldehyde under reducing conditions, and it is also possible to use other protecting groups instead of Boc. This amination can be conducted analogously to A. Beni et al. (Chem. Eur. J. 2008, 14, 1804-1813). The reaction product is deprotected and reacted under reducing conditions with a further aldehyde, which may be the same as or different than the first aldehyde. In this way, it is possible to synthesize a ligand having two identical arms and one different arm or having three identical arms. Correspondingly, using two different amine protecting groups with different detachment conditions, it is also possible to synthesize ligands having three different arms. By means of Hartwig-Buchwald cross-coupling reactions, it is correspondingly possible to synthesize aromatic analogs.

A further option for the preparation of a secondary amine is, for example, the reaction of an ethene derivative with ammonium chloride, as shown in general terms in Scheme 2 below (reaction analogous to K. Ladomenou et al., Tetrahedron 2007, 63, 2882-2887). This secondary amine can then be converted further to the tertiary amine, for example, analogously to the reaction shown in Scheme 1.

One possible synthesis of tertiary phosphines having two different arms is shown in Scheme 3 below.

In this scheme, R′ and R″ are the same or different at each instance and are an alkyl, aryl or heteroaryl group as defined above for R, and X is Cl, Br or I.

The synthesis can be conducted analogously to A. Tsurusaki et al., Bull. Chem. Soc. Jpn. 2010, 83(5), 456-478. For this purpose, an aryl halide, heteroaryl halide or alkyl halide is lithiated and reacted with a diprotected phosphine chloride, it being possible to use other protecting groups as well rather than NEt₂. The reaction product is deprotected to give the corresponding phosphine dichloride and reacted with a Grignard reagent to give the tertiary phosphine. In this way, it is possible to synthesize a ligand having two identical arms and one different arm or having three identical arms. Correspondingly, using two different phosphine protecting groups with different detachment conditions, it is also possible to synthesize ligands having three different arms.

The complexes of formula (1) or according to the preferred embodiments detailed above are preparable in principle by various methods. In order to obtain an uncharged metal complex, the magnitude of the charge of the ligand must compensate for the charge of the metal. For this purpose, the metal complex is reacted with the free ligand, if appropriate in deprotonated form.

The deprotonation of the ligand can be effected in situ by means of a metal precursor with a protonatable, preferably non-nucleophilic counterion, for example mesityl or amide. This directly affords the uncharged metal complex of the formula (1).

Alternatively, it is first possible to deprotonate the ligand with a base and then react it with a metal salt which replaces the cation of the deprotonated ligand. In that case, the uncharged metal complex is obtained directly.

A third option is that of reacting a metal salt with the non-deprotonated ligand. This forms, as an intermediate, a positively charged metal complex which can then be deprotonated to give the uncharged complex.

The synthesis of cryptates can be effected, for example, by reaction of a complex having an appropriate tripodal ligand with a bridging unit, as shown by an example in Scheme 4 below.

The present invention thus further provides a process for preparing the inventive compounds, characterized by the reaction of a metal salt or metal complex of the metal M with the corresponding free ligands, optionally in deprotonated form. When the ligand is not used in deprotonated form, it is optionally possible to conduct a deprotonation step after the complexation. More particularly, metal salts or metal complexes having a protonatable, non-nucleophilic counterion are used.

Examples of suitable copper compounds which can be used as reactants are especially copper(I) salts having weakly coordinating anions, such as Cu(OAc), Cu₂(CO₃), [Cu(MeCN)₄][BF₄], CuBF₄, [Cu(MeCN)₄][PF₆], copper(I) mesityl or copper(I) amides, for example copper(I) pyrrolidine.

Examples of suitable silver compounds which can be used as reactants are especially silver(I) salts having weakly coordinating anions, such as Ag(OAc), Ag₂(CO₃), [Ag(MeCN)₄][BF₄], AgBF₄, [Ag(MeCN)₄][PF], silver(I) mesityl or silver(I) amides, for example silver(I) pyrrolidine. Examples of suitable gold compounds which can be used as reactants are [Au(PR₃)(MeCN)][SbF₆], AuHal.SR₂. [Au(PR₃)(N(SO₂)₂(CF₃)₂)] and gold(I) mesityl, where Hal is a halide and R is an alkyl group having 1 to 5 carbon atoms or an aryl group having 6 to 10 aromatic ring atoms. Examples of suitable zinc compounds which can be used as reactants are ZnMe₂, Zn(OAc)₂, [Zn(TMHD)₂](CAS: 14363-14-5) and [Zn(dibutyldithiocarbamate)]. Examples of suitable aluminum compounds which can be used as reactants are AlMe₃, Al(OH)₃, Al(NO₃)₃, Al₂(SO₄)₃, Al(sec-butoxide)₃, Al(OAc)₃, AlPO₄, Al(acac)₃ and Al(ethoxide)₃.

The synthesis can also be activated by thermal or photochemical means or by means of microwave radiation and/or conducted in an autoclave or generally under pressure. By means of these processes, it is possible to obtain the complexes in high purity, preferably in a purity of >99% by ¹H NMR or HPLC.

For processing from solution, for example by spin-coating or by printing methods, solutions or formulations of the compounds of the invention are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore further provides a formulation comprising a compound of the invention and at least one further compound. The further compound may, for example, be one or more solvents, especially one or more of the abovementioned solvents. The way in which such solutions can be prepared is known to those skilled in the art and is described, for example, in WO 2002/072714, WO 2003/019694 and the literature cited therein. The further compound may alternatively be a further organic or inorganic compound which is likewise used in the electronic device, for example a matrix material. This further compound may also be polymeric.

The above-described compounds of formula (1) and the above-detailed preferred embodiments can be used as active component in an electronic device. The present invention therefore further provides for the use of a compound of formula (1) or according to one of the preferred embodiments in an electronic device. In addition, the compounds of the invention can be used for production of singlet oxygen, in photocatalysis or in oxygen sensors.

The present invention still further provides an electronic device comprising at least one compound of formula (1) or according to one of the preferred embodiments.

An electronic device is understood to mean any device comprising anode, cathode and at least one layer, said layer comprising at least one organic or organometallic compound. The electronic device of the invention thus comprises anode, cathode and at least one layer comprising at least one compound of the above-detailed formula (1). Preferred electronic devices are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) and organic laser diodes (O-lasers), comprising at least one compound of the above-detailed formula (1) in at least one layer. Particular preference is given to organic electroluminescent devices. Active components are generally the organic or inorganic materials introduced between the anode and cathode, for example charge injection, charge transport or charge blocker materials, but especially emission materials and matrix materials. The compounds of the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may comprise further layers, for example in each case one or more hole injection layers, hole transport layers, hole blocker layers, electron transport layers, electron injection layers, exciton blocker layers, electron blocker layers, charge generation layers and/or organic or inorganic p/n junctions. It is likewise possible for interlayers to be introduced between two emitting layers, these having, for example, an exciton-blocking function and/or controlling the charge balance in the electroluminescent device. However, it should be pointed out that not necessarily each of these layers need be present.

It is possible for the organic electroluminescent device to contain one emitting layer, or for it to contain a plurality of emitting layers. If a plurality of emission layers are present, these preferably have several emission maxima between 380 nm and 750 mm overall, such that the overall result is white emission; in other words, various emitting compounds which may fluoresce or phosphoresce are used in the emitting layers. A preferred embodiment is three-layer systems where the three layers exhibit blue, green and orange or red emission (see, for example, WO 2005/011013), or systems having more than three emitting layers. A further preferred embodiment is two-layer systems where the two layers exhibit either blue and yellow emission or blue-green and orange emission. Two-layer systems are of interest especially for lighting applications. Embodiments of this kind are particularly suitable with the compounds of the invention, since they frequently exhibit yellow or orange emission. The white-emitting electroluminescent devices can be used for lighting applications or as a backlight for displays or with color filters as a display.

In a preferred embodiment of the invention, the organic electroluminescent device comprises the compound of formula (1) or the above-detailed preferred embodiments as emitting compound in one or more emitting layers. This is especially true when M is Cu, Ag or Au.

When the compound of formula (1) is used as emitting compound in an emitting layer, it is preferably used in combination with one or more matrix materials. The mixture of the compound of formula (1) and the matrix material contains between 1% and 99% by volume, preferably between 2% and 90% by volume, more preferably between 3% and 40% by volume and especially between 5% and 15% by volume of the compound of formula (1), based on the overall mixture of emitter and matrix material. Correspondingly, the mixture contains between 99% and 1% by volume, preferably between 98% and 10% by volume, more preferably between 97% and 60% by volume and especially between 95% and 85% by volume of the matrix material(s), based on the overall mixture of emitter and matrix material.

The matrix materials used may generally be any materials which are known for the purpose according to the prior art. The triplet level of the matrix material is preferably higher than the triplet level of the emitter.

Suitable matrix materials for the compounds of the invention are ketones, phosphine oxides, sulfoxides and sulfones, for example according to WO 2004/013080, WO 2004/093207, WO 2006/005627 or WO 2010/006680, triarylamines, carbazole derivatives, e.g. CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example according to WO 2007/063754 or WO 2008/056746, indenocarbazole derivatives, for example according to WO 2010/136109 or WO 2011/000455, azacarbazoles, for example according to EP 1617710, EP 1617711, EP 1731584, JP 2005/347160, bipolar matrix materials, for example according to WO 2007/137725, silanes, for example according to WO 20051111172, azaboroles or boronic esters, for example according to WO 2006/117052, diazasilole derivatives, for example according to WO 2010/054729, diazaphosphole derivatives, for example according to WO 2010/054730, triazine derivatives, for example according to WO 2010/015306, WO 2007/063754 or WO 2008/056746, zinc complexes, for example according to EP 652273 or WO 2009/062578, dibenzofuran derivatives, for example according to WO 2009/148015, or bridged carbazole derivatives, for example according to US 2009/0136779, WO 2010/050778, WO 2011/042107 or WO 2011/088877.

It may also be preferable to use a plurality of different matrix materials as a mixture. Especially suitable for this purpose are mixtures of at least one electron-transporting matrix material and at least one hole-transporting matrix material or mixtures of at least two electron-transporting materials or mixtures of at least one hole- or electron-transporting matrix material and at least one further material which has a large bandgap and is thus substantially electrically inert and is not involved to a substantial extent, if any, in the charge transport, as described, for example, in WO 2010/108579.

In addition, it may be preferable to use the compound of the invention as matrix material, especially as matrix material for triplet emitters. This is especially true when M is Zn.

In addition, it may be preferable to use the compound of the invention as electron transport material or as hole blocker material. This is especially true when M is Al.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. On the other hand, metal/metal oxide electrodes (e.g. Al/Ni/NiOx, Al/PtOx) may also be preferred. For some applications, at least one of the electrodes has to be transparent in order to enable the irradiation of the organic material (O-SC) or the emission of light (OLED/PLED, O-laser). A preferred structure uses a transparent anode. Preferred anode materials here are conductive mixed metal oxides. Particular preference is given to indium tin oxide (ITO) or indium zinc oxide (IZO). Preference is further given to conductive doped organic materials, especially conductive doped polymers.

In the further layers, it is generally possible to use any materials as used according to the prior art for the layers, and the person skilled in the art is able, without exercising inventive skill, to combine any of these materials with the materials of the invention in an electronic device.

The device is correspondingly (according to the application) structured, contact-connected and finally hermetically sealed, since the lifetime of such devices is severely shortened in the presence of water and/or air.

Additionally preferred is an organic electroluminescent device, characterized in that one or more layers are coated by a sublimation process. In this case, the materials are applied by vapor deposition in vacuum sublimation systems at an initial pressure of typically less than 10⁻⁵ mbar, preferably less than 10⁻⁶ mbar. It is also possible that the initial pressure is even lower, for example less than 10⁻⁷ mbar.

Preference is likewise given to an organic electroluminescent device, characterized in that one or more layers are coated by the OVPD (organic vapor phase deposition) method or with the aid of a carrier gas sublimation. In this case, the materials are applied at a pressure between 10⁻⁵ mbar and 1 bar. A special case of this method is the OVJP (organic vapor jet printing) method, in which the materials are applied directly by a nozzle and hence structured (for example M. S. Arnold et al., Appl. Phys. Lett. 2008, 92, 053301).

Preference is additionally given to an organic electroluminescent device, characterized in that one or more layers are produced from solution, for example by spin-coating, or by any printing method, for example screen printing, flexographic printing or offset printing, but more preferably LITI (light-induced thermal imaging, thermal transfer printing) or inkjet printing. For this purpose, soluble compounds are needed, which are obtained, for example, through suitable substitution.

The organic electroluminescent device can also be produced as a hybrid system by applying one or more layers from solution and applying one or more other layers by vapor deposition. For example, it is possible to apply an emitting layer comprising a compound of formula (1) and a matrix material from solution, and to apply a hole blocker layer and/or an electron transport layer thereto by vapor deposition under reduced pressure.

These methods are known in general terms to those skilled in the art and can be applied without difficulty to organic electroluminescent devices comprising compounds of formula (1) or the above-detailed preferred embodiments.

The electronic devices of the invention, especially organic electroluminescent devices, are notable for the following surprising advantages over the prior art:
1. In contrast to many metal complexes according to the prior art which are subject to partial or complete pyrolytic breakdown on sublimation, the compounds of the invention have high thermal stability. Especially the uncharged compounds according to the present invention have a surprisingly low sublimation temperature.
2. Organic electroluminescent devices comprising the compounds of the invention as emitting materials, as matrix materials or as electron transport materials have broad good properties in relation to efficiency, operating voltage and lifetime.
3. The compounds of formula (1) are not based on the scarce metals iridium or platinum, which contributes to protecting resources of these metals.
4. The complexes of formula (1) or according to the above-detailed preferred embodiments have good synthetic obtainability, in high yields and high purities.

The abovementioned advantages are not accompanied by a deterioration in the further electronic properties.

The invention is illustrated in detail by the examples which follow, without any intention of restricting it thereby. The person skilled in the art is able to produce further complexes of the invention from the details given without exercising inventive skill, and to use them in organic electronic devices or to employ the process of the invention, and hence to execute the invention over the entire scope claimed.

### DESCRIPTION OF THE FIGURES

FIG. 1: Crystal structure of [Cu(InPEA)](BF₄), showing the distorted tetrahedral coordination of the ligand to the Cu (the protons and the BF₄ anion are not shown in the interests of clarity).

FIG. 2: Absorption and emission spectrum of [Cu(InPEA)](BF₄) in solid form (pure material; emission maximum: 519 nm, yellow-green emission).

FIG. 3: Absorption and emission spectrum of [Cu(InPEA)](BF₄) in solution in dichloromethane (emission maximum: 464 nm, blue emission).

FIG. 4: Absorption and emission spectrum of [Cu(InPEA)] in solution in dichloromethane (emission maximum: 506 nm, yellow-green emission).

FIG. 5: Crystal structure of [Cu(OPEA)](BF₄), showing the distorted tetrahedral coordination of the ligand to the Cu (the protons and the BF₄ anion are not shown in the interests of clarity).

FIG. 6: Absorption and emission spectrum of [Cu(OPEA)](BF₄) in solid form (pure material; emission maximum: 525 nm, yellow-green emission).

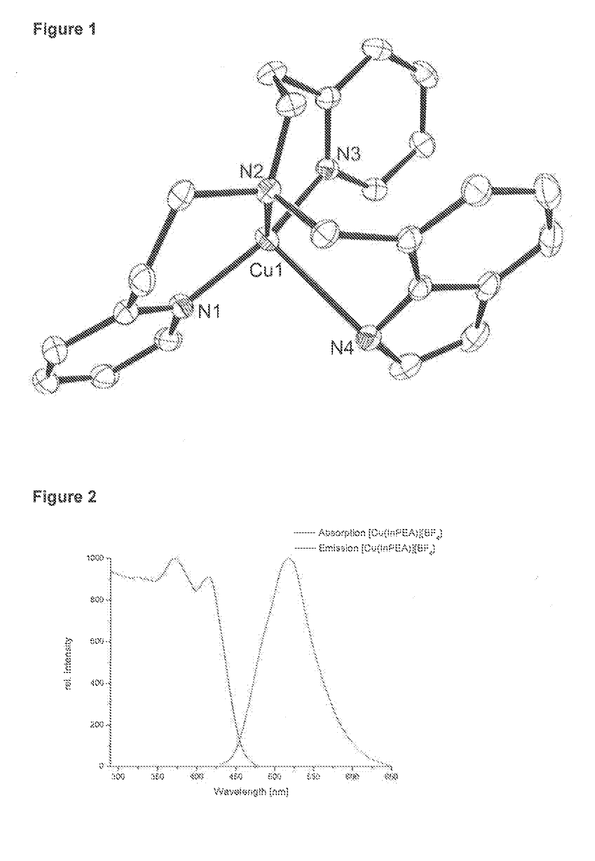

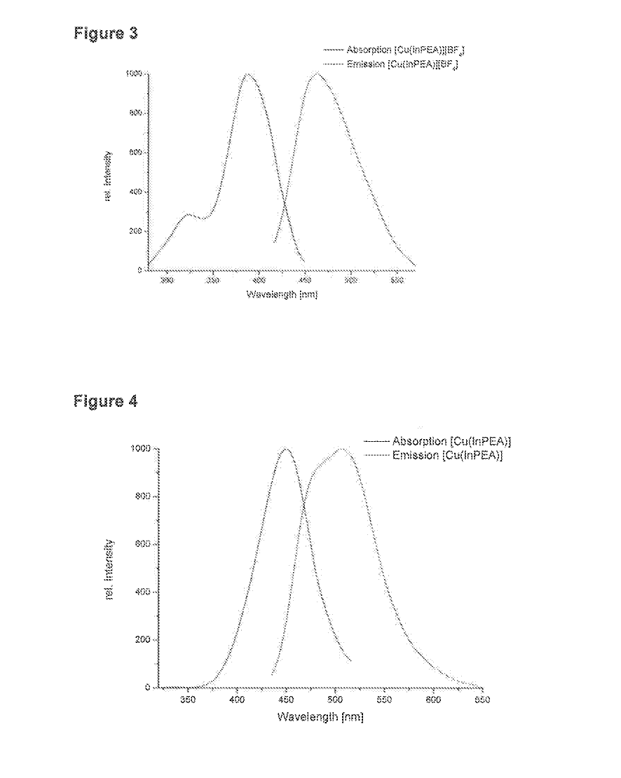

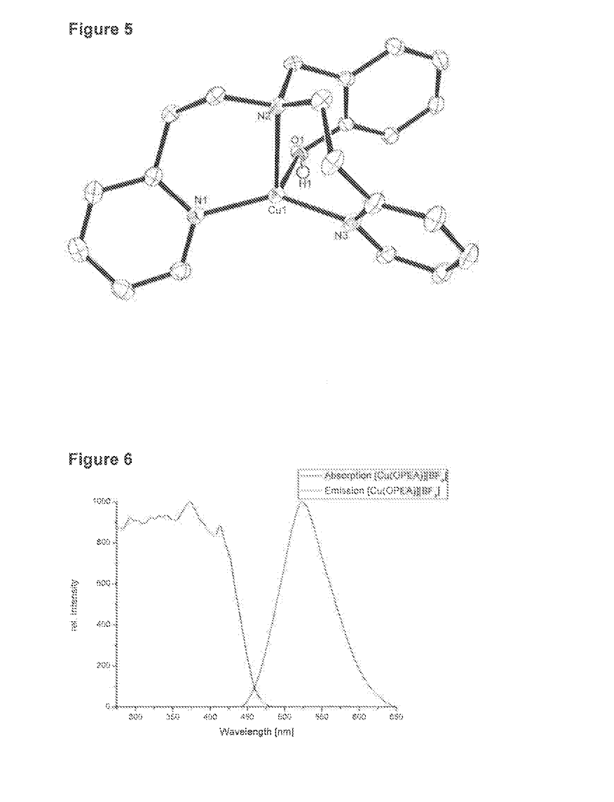

### EXAMPLES

The syntheses which follow, unless stated otherwise, are conducted under a protective gas atmosphere in dried solvents. The solvents and reagents can be purchased from ALDRICH or ABCR.

### Example 1

### Synthesis of the InPEA ligand (N-((1H-indol-7-yl)methyl)-2-(pyridin-2-yl)-N-(2-(pyridin-2-yl)ethyl)ethanamine)

Step 1:

In a 250 mL Schlenk flask, 1.25 g of bis(2-(pyridin-2-yl)ethyl)amine (5.51 mmol) (synthesized according to K. Ladomenou et al., Tetrahedron 2007, 63, 2882-2887) and 1.35 g of N-Boc-indole-7-carbadehyde (CAS: 597544-14-4) (5.51 mmol) are inertized and then dissolved in 30 mL of dichloromethane. Subsequently, an inert suspension of 1.63 g of sodium triacetoxyborohydride (7.71 mmol) in 30 mL of DCM is added. The reaction mixture is stirred at RT for 18 h. Thereafter, 80 mL of saturated NaHCO₃ solution are added and the mixture is stirred for another 30 min. Then the mixture is extracted three times with dichloromethane, dried over MgSO₄ and concentrated under reduced pressure. There is no further purification of the orange oil obtained; it is used further directly.

Step 2:

In a 30 mL pressure vessel, the synthesized product from step 1 is dissolved in 4 mL of THF under a protective gas atmosphere and then 16 mL of NaOMe solution (0.57 M in MeOH) are added. The vessel is sealed pressure-tight and stirred in a microwave at 150° C. for 3 h. In the course of this, the pressure rises continuously to 27 bar. Once the pressure remains constant, the vessel is cooled to room temperature, and the reaction mixture is added to 60 mL of H₂O, then extracted three times with 30 mL each time of ether, dried over MgSO₄ and concentrated under reduced pressure. Purification is then effected in a short silica gel column (pure ethyl acetate, R_{f}=0.04). The product is a colorless solid. Yield 58%.

¹H NMR (DCM-d₂, 400.13 MHz): δ 10.70 (bs, 1H), 8.39 (m, 2H), 7.52 (m, 1H), 7.48 (m, 2H), 7.09-7.11 (m, 1H), 7.06 (m, 2H), 6.97 (m, 2H), 6.90 (m, 2H), 6.44 (m, 1H), 3.98 (s, 2H), 2.82-2.86 (s, 8H). ¹³C NMR (DCM-d₂, 100.13 MHz): δ 161.49, 149.35, 136.72, 135.93, 128.55, 124.89, 123.58, 123.06, 121.82, 121.54, 119.97, 119.30, 101.55, 58.04, 54.62, 36.00.

### Example 2

### Synthesis of [Cu(InPEA)][BF₄]

204.0 mg (0.57 mmol) of InPEA from example 1 and 180.0 mg (0.57 mmol) of [Cu(MeCN)₄][BF₄] are inertized in a Schlenk flask, dissolved in 30 ml of THF and stirred at room temperature for 2 h. This forms a yellow-brown suspension. The suspension is filtered and diethyl ether is allowed to diffuse in. This forms yellow crystals.

¹H NMR (DCM-d₂, 400.13 MHz): δ 9.33 (bs, 1H), 8.17 (m, 2H), 7.73 (m, 2H), 7.34 (m, 1H), 7.32 (m, 1H), 7.24 (m, 2H), 7.17-7.21 (m, 2H), 7.00 (m, 1H), 7.86 (m, 1H), 6.50 (m, 1H), 4.01 (s, 2H), 3.05-3.27 (m, 8H).

¹³C{¹H}NMR(DCM-d₂, 100.13 MHz): δ 160.67, 150.44, 146.34, 139.34, 130.01, 127.17, 125.92, 123.51, 123.33, 121.39, 120.56, 120.18, 104.64, 56.51, 54.47, 36.22.

The [Cu(InPEA)][BF₄] salt can be deprotonated, for example, with potassium tert-butoxide (KOtBu). The [Cu(InPEA)] product, i.e. the uncharged complex, can be identified unambiguously by the ¹H NMR spectrum.

### Example 3

### Synthesis of [Cu(InPEA)]

191.1 mg (0.54 mmol) of InPEA from example 1 and 98.0 mg (0.54 mmol) of Cu-mesityl are dissolved in 4 ml of toluene in a glovebox and stirred at room temperature for 1 h. This forms an orange solution. This solution is filtered and the solvent is removed under reduced pressure. The pure complex is obtained by sublimation at 1·10⁻² mbar and 180° C.

¹H NMR (DCM-d₂, 400.13 MHz): δ 8.40 (m, 2H), 7.60 (m, 2H), 7.49 (m, 1H), 7.42-7.45 (m, 1H), 7.13 (m, 2H), 7.06 (m, 2H), 6.77-6.82 (m, 2H), 6.44 (m, 1H), 4.10-4.34 (m, 2H), 2.68-2.99 (m, 8H).

### Example 4

### Synthesis of the InPA ligand (N-((1H-indol-7-yl)methyl)-1-(pyridin-2-yl)-N-(pyridin-2-ylmethyl)methanamine)

Step 1:

In a 250 mL Schlenk flask, 1.02 g of di(2-picolyl)amine (CAS: 1539-42-0) (5.14 mmol) and 1.26 g of N-Boc-indole-7-carbaldehyde (CAS: 597544-14-4) (5.14 mmol) were inertized and then dissolved in 30 mL of dichloromethane. Subsequently, an inert suspension of 1.52 g of sodium triacetoxyborohydride (7.19 mmol) in 40 mL of dichloromethane is added. The reaction mixture is stirred at room temperature for 18 h. Thereafter, 70 mL of saturated NaHCO₃ solution are added and the mixture is stirred for another 30 min. Then the mixture is extracted three times with dichloromethane, dried over MgSO₄ and concentrated under reduced pressure. There is no further purification of the orange oil obtained. Yield 99%.

¹H NMR (DCM-d₂, 400.13 MHz): δ 8.57 (m, 2H), 7.58-7.67 (m, 4H), 7.48-7.53 (m, 3H), 7.27 (m, 1H), 7.11 (m, 2H), 6.63 (m, 1H), 4.39 (s, 2H), 3.85 (s, 4H), 1.65 (s, 9H).

¹³C NMR (DCM-d₂, 100.13 MHz): δ 159.76, 149.98, 149.27, 136.28, 134.43, 132.55, 128.75, 127.42, 126.45, 123.56, 123.36, 122.11, 120.45, 107.47, 83.67, 58.99, 58.92, 28.35.

Step 2:

In a 30 mL pressure vessel, under a protective gas atmosphere, 2.19 g of Boc-InPA (5.11 mmol) from step 1 are dissolved in 8 mL of THF and then 12 mL of NaOMe solution (0.57 M in MeOH) are added. The vessel is sealed pressure-tight and stirred in a microwave at 130° C. for 2 h. In the course of this, the pressure rises continuously to 27 bar. Once the pressure remains constant, the vessel is cooled to room temperature, and the reaction mixture is added to 60 mL of H₂O, then extracted three times with 30 mL each time of ether, dried over MgSO₄ and concentrated under reduced pressure. Purification is then effected with a silica gel column (pure ethyl acetate, R_{f}=0.28). The product is a colorless solid. Yield 63%.

¹H NMR (DCM-d₂, 400.13 MHz): δ 12.55 (bs, 1H), 8.66 (m, 2H), 7.67 (m, 1H), 7.59 (m, 2H), 7.55-7.57 (m, 1H), 7.29 (m, 2H), 7.08-7.18 (m, 4H), 6.63-6.67 (m, 1H), 4.01 (s, 2H), 3.95 (s, 4H).

¹³C NMR (DCM-d₂, 100.13 MHz): δ 160.08, 149.40, 136.98, 136.41, 128.69, 124.86, 123.73, 123.15, 122.52, 121.97, 120.26, 119.26, 101.57, 60.11, 57.65.

Elemental analysis: calculated (%) for C₂₁H₂₀N₄ (328.41 g/mol): C, 76.80; H, 6.14; N, 17.06. found: C, 76.44; H, 6.09; N, 17.02.

### Example 5

### Synthesis of the PBPA ligand (N-(2-(1H-pyrrol-2-yl)benzyl)-1-(pyridin-2-yl)-N-(pyridin-2-ylmethyl)methanamine)

Step 1:

In a 250 mL Schienk flask, 868.1 mg of di(2-picolyl)amine (4.36 mmol) and 1.182 g of tert-butyl 2-(2-formylphenyl)-1H-pyrrole-1-carboxylate (CAS: 445262-65-7) (4.36 mmol) were inertized and then dissolved in 20 mL of dichloromethane. Subsequently, an inert suspension of 1.293 g of sodium triacetoxyborohydride (6.10 mmol) in 30 mL of dichloromethane is added. The reaction mixture is stirred at room temperature for 18 h. Thereafter, 60 mL of saturated NaHCO₃ solution are added and the mixture is stirred for another 30 min. Then the mixture is extracted three times with dichloromethane, dried over MgSO₄ and concentrated under reduced pressure. There is no further purification of the orange oil obtained. Yield 95%.

¹H NMR (DCM-d₂, 250.13 MHz): δ 8.51 (m, 2H), 7.94 (m, 1H), 7.58-7.71 (m, 5H), 7.46 (m, 1H), 7.25-7.28 (m, 1H), 7.07-7.17 (m, 3H), 6.32 (m, 1H), 6.15 (m, 1H), 3.52-3.85 (m, 6H), 1.20 (s, 9H).

¹³C NMR (DCM-d₂, 62.90 MHz): δ 160.38, 149.47, 149.37, 139.75, 136.70, 135.28, 133.21, 131.05, 128.56, 128.40, 126.52, 122.99, 122.29, 121.94, 114.73, 110.95, 83.60, 60.77, 56.21, 27.70.

Step 2:

In a 30 mL pressure vessel, under a protective gas atmosphere, 1.2 g of Boc-PBPA (2.64 mmol) from step 1 are dissolved in 8 mL of THF and then 12 mL of NaOMe solution (0.57 M in MeOH) are added. The vessel is sealed pressure-tight and stirred in a microwave at 150° C. for 3 h. In the course of this, the pressure rises continuously to 23 bar. Thereafter, the vessel is cooled to room temperature, and the reaction mixture is added to 60 mL of H₂O, then extracted three times with 30 mL each time of ether, dried over MgSO₄ and concentrated under reduced pressure. Purification is then effected using a silica gel column (pure ethyl acetate, R_{f}=0.28). The product is a colorless oil. Yield 71%.

¹H NMR (DCM-d₂, 400.13 MHz): δ 12.89 (bs, 1H), 8.59 (m, 2H), 7.66 (m, 1H), 7.55 (m, 2H), 7.39 (m, 1H), 7.33 (m, 1H), 7.22 (m, 2H), 7.17 (m, 1H), 7.10-7.14 (m, 2H), 6.99-7.02 (m, 1H), 6.46-6.49 (m, 1H), 6.27-6.30 (m, 1H), 3.93 (s, 2H), 3.92 (s, 4H).

¹³C NMR (DCM-d₂, 100.13 MHz): δ 158.81, 149.84, 136.61, 135.45, 134.04, 132.81, 132.66, 129.07, 128.83, 126.02, 124.19, 122.54, 120.20, 109.05, 107.88, 61.06, 60.30.

### Example 6

### Synthesis of the OPEA ligand (2-((bis(2-(pyridin-2-yl)ethyl)amino)methyl)phenol)

In a 250 mL Schlenk flask, 2.40 g of bis(2-(pyridin-2-yl)ethyl)amine (10 mmol) and 1.29 g of salicylaldehyde (10 mmol) were inertized and then dissolved in 80 mL of dichloromethane. Subsequently, an inert suspension of 3.13 g of sodium triacetoxyborohydride (15 mmol) in 80 mL of dichloromethane is added. The reaction mixture is stirred at room temperature for 18 h. Thereafter, 160 mL of saturated NaHCO₃ solution are added and the mixture is stirred for another 30 min. Then the mixture is extracted three times with dichloromethane, dried over MgSO₄ and concentrated under reduced pressure. The resultant yellow oil is purified using a 7 cm silica gel column (pure ethyl acetate, R_{f}=0.08). Yield 84%.

¹H NMR (DCM-d₂, 400.13 MHz): δ 10.21 (bs, 1H), 8.53 (m, 2H), 7.54 (m, 2H), 7.16 (m, 1H), 7.05-7.11 (m, 4H), 7.03 (m, 1H), 6.76-6.83 (m, 2H), 3.87 (s, 2H), 2.97-3.10 (s, 8H).

¹³C NMR (DCM-d₂, 100.13 MHz): δ 160.00, 158.45, 149.62, 136.65, 129.19, 128.99, 123.58, 122.78, 121.67, 119.31, 116.33, 58.04, 53.34, 35.09.

### Example 7

### Synthesis of [Cu(OPEA)][BF₄]

333.3 mg (1 mmol) of OPEA from example 6 and 314.6 mg (1 mmol) of [Cu(MeCN)₄][BF₄] are inertized in a Schlenk flask, dissolved in 40 ml of THF and stirred at room temperature for 2 h. This forms a yellow solution. This solution is filtered and blanketed with n-hexane. This forms yellow crystals. Yield: 91%.

¹H NMR (DCM-d₂, 400.13 MHz): δ 8.80 (m, 2H), 8.46 (bs, 1H), 7.69 (m, 2H), 7.28 (m, 2H), 7.18 (m, 2H), 6.96 (m, 1H), 6.89 (m, 1H), 6.85 (m, 1H), 6.61 (m, 1H), 3.66 (s, 2H), 2.80-3.18 (m, 8H). ¹³C{¹H}NMR(DCM-d₂, 100.13 MHz): δ 160.18, 155.01, 151.65, 138.52, 132.48, 130.28, 125.18, 123.67, 122.34, 120.51, 116.38, 57.22, 55.98, 36.10.

Elemental analysis calculated (%) for C₂₁H₂₃BCUF₄N₃O (483.78 g/mol): C, 52.14; H, 4.79; N, 8.69. Found: C, 52.05; H, 4.64; N, 8.67.

### Example: Production of the OLEDs

1) Vacuum-Processed Devices

OLEDs of the invention and OLEDs according to the prior art are produced by a general method according to WO 2004/058911, which is adapted to the circumstances described here (variation in layer thickness, materials used).

In the examples which follow, the results for various OLEDs are presented. Glass plates with structured ITO (50 nm, indium tin oxide) form the substrates to which the OLEDs are applied. The OLEDs basically have the following layer structure: substrate/hole transport layer 1 (HTL1) consisting of HTM doped with 3% NDP-9 (commercially available from Novaled),

20 nm/hole transport layer 2 (HTL2)/optional electron blocker layer (EBL)/emission layer (EML)/optional hole blocker layer (HBL)/electron transport layer (ETL)/optional electron injection layer (EIL) and finally a cathode. The cathode is formed by an aluminum layer of thickness 100 nm.

First of all, vacuum-processed OLEDs are described. For this purpose, all the materials are applied by thermal vapor deposition in a vacuum chamber. In this case, the emission layer always consists of at least one matrix material (host material) and an emitting dopant (emitter) which is added to the matrix material(s) in a particular proportion by volume by co-evaporation. Details given in such a form as M1:M2:[Cu(InPEA)](55%:35%:10%) mean here that the material M1 is present in the layer in a proportion by volume of 55%, M2 in a proportion of 35% and [Cu(InPEA)]in a proportion of 10%. Analogously, the electron transport layer may also consist of a mixture of two materials. The exact structure of the OLEDs can be found in table 1. The materials used for production of the OLEDs are shown in table 4.

The OLEDs are characterized in a standard manner. For this purpose, the electroluminescence spectrum, the power efficiency (measured in cd/A) and the voltage (measured at 1000 cd/m² in V) are determined from current-voltage-brightness characteristics (IUL characteristics).

Use of Compounds of the Invention as Emitter Materials in OLEDs

One use of the compounds of the invention is as emitter materials in the emission layer in OLEDs.

TABLE 1
Structure of the OLED

| | | | | | |
|---|---|---|---|---|---|
| | HTL2 | EBL | EML | HBL | ETL |
| | thick- | thick- | thick- | thick- | thick- |
| Ex. | ness | ness | ness | ness | ness |

Red OLEDs

| | | | | | |
|---|---|---|---|---|---|
| D1 | HTM | — | M1:M2:[Cu(InPEA)] | — | ETM1:ETM2 |
| | 230 nm | | (65%:30%:5%) | | (50%:50%) |
| | | | 35 nm | | 40 nm |
| D2 | HTM | — | M1:M2:[Cu(InPEA)] | — | ETM1:ETM2 |
| | 230 nm | | (60%:30%:10%) | | (50%:50%) |
| | | | 35 nm | | 40 nm |
| D3 | HTM | 10 nm | M1:M2:[Cu(InPEA)] | — | ETM1:ETM2 |
| | 220 nm | | (65%:30%:5%) | | (50%:50%) |
| | | | 35 nm | | 40 nm |

TABLE 2
Results for the vacuum-processed OLEDs

| | EQE (%) | Voltage (V) | CIE x/y |
|---|---|---|---|
| Ex. | 1000 cd/m² | 1000 cd/m² | 1000 cd/m² |
| D1 | 9.4 | 3.9 | 0.51/0.40 |
| D2 | 11.7 | 3.7 | 0.51/0.41 |
| D3 | 17.2 | 4.2 | 0.49/0.43 |

2) Solution-Processed Devices Made from Soluble Functional Materials

The complexes of the invention may also be processed from solution and lead therein to OLEDs which are simpler in terms of process technology compared to the vacuum-processed OLEDs, but nevertheless have good properties. The production of such components is based on the production of polymeric light-emitting diodes (PLEDs), which has already been described many times in the literature (for example in WO 2004/037887). The structure is composed of substrate/ITO/PEDOT (80 nm)/interlayer (80 nm)/emission layer (80 nm)/cathode. For this purpose, substrates from Technoprint (soda-lime glass) are used, to which the ITO structure (indium tin oxide, a transparent conductive anode) is applied. The substrates are cleaned in a cleanroom with DI water and a detergent (Deconex 15 PF) and then activated by a UVIozone plasma treatment. Thereafter, likewise in the cleanroom, as a buffer layer, an 80 nm layer of PEDOT (PEDOT is a polythiophene derivative (Baytron P VAI 4083sp.) from H. C. Starck, Goslar, which is supplied as an aqueous dispersion) is applied by spin-coating. The required spin rate depends on the degree of dilution and the specific spin-coater geometry (typical value for 80 nm: 4500 rpm). In order to remove residual water from the layer, the substrates are baked on a hotplate at 180° C. for 10 minutes. The interlayer used serves for hole injection; in this case, HIL-012 from Merck is used. The interlayer may alternatively also be replaced by one or more layers which merely have to fulfill the condition of not being leached off again by the subsequent processing step of EML deposition from solution. For production of the emission layer, the emitters of the invention are dissolved together with the matrix materials in toluene or THF. The typical solids content of such solutions is between 16 and 25 g/L when, as here, the layer thickness of 80 nm which is typical of a device is to be achieved by means of spin-coating. The solution-processed devices contain an emission layer composed of (polystyrene):M3:M4:emitter (25%:25%:40%:10%). The emission layer is spun on in an inert gas atmosphere, argon in the present case, and baked at 130° C. for 30 min. Lastly, a cathode composed of barium (5 nm) and then aluminum (100 nm) (high-purity metals from Aldrich, particularly barium 99.99% (cat. no. 474711); vapor deposition systems from Lesker or the like, typical vapor deposition pressure 5×10⁻⁶ mbar) is applied by vapor deposition. It is optionally possible first to apply a hole blocker layer and then an electron transport layer and only then the cathode (e.g. Al or LiF/Al) by vapor deposition under reduced pressure. In order to protect the device from air and air humidity, the device is finally encapsulated and then characterized. The OLED examples cited are yet to be optimized; table 3 summarizes the data obtained.

TABLE 3
Results with materials processed from solution

| | | EQE (%) | Voltage (V) | CIE x/y |
|---|---|---|---|---|
| Ex. | Emitter | 1000 cd/m² | 1000 cd/m² | 1000 cd/m² |
| Sol-D1 | [Cu(InPEA)] | 8.8 | 4.9 | 0.51/0.40 |
| Sol-D2 | [Cu(InPEA)][BF₄] | 6.7 | 5.7 | 0.52/0.28 |
| Sol-D3 | [Cu(OPEA)][BF₄] | 7.0 | 5.5 | 0.55/0.38 |

```
TABLE 4
Structural formulae of the materials used
  HTM
  EBM
  M1
  M2
  M3
  M4
  ETM1
  ETM2
```

1-14. (canceled)

15. A compound of formula (1):
wherein
M is selected from the group consisting of Cu, Ag, Au, Zn, and Al;
A is selected from the group consisting of N and P;
Y is the same or different in each instance and is a bivalent group selected from the group consisting of CR₂, O, S, 1,2-vinylene, 1,2-phenylene, 1,3-phenylene, and ortho-bonded heteroarylene groups having 5 or 6 aromatic ring atoms, wherein each of these groups is optionally substituted by one or more R radicals;
L¹, L², and L³
is the same or different in each instance and is a heteroaryl group having 5 to 25 aromatic ring atoms, is optionally substituted by one or more R radicals, and contains a nitrogen, sulphur, or oxygen atom optionally coordinated to M, or is an aryl or heteroaryl group having 5 to 18 aromatic ring atoms, is optionally substituted by one or more R radicals, and has an exocyclic donor atom selected from the group consisting of N, O, S, and P coordinated to M and is optionally substituted by one or more R radicals; and wherein L¹, L², and L³ are optionally bridged to one another via R radicals;
n is the same or different in each instance and is 0, 1, 2, 3, 4, or 5;
R is the same or different in each instance and is H, D, F, Cl, Br, I, N(R¹)₂, CN, NO₂, OR¹, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms, a branched or cyclic alkyl, alkoxy or thioalkoxy group having 3 to 40 carbon atoms, an alkenyl or alkynyl group having 2 to 40 carbon atoms, each of which is optionally substituted by one or more R¹ radicals, wherein one or more nonadjacent CH₂ groups is optionally replaced by R¹C═CR¹, C≡C, Si(R¹)₂, C═O, C═S, C═NR¹, P(═O)(R¹), SO, SO₂, NR¹, O, S, or CONR¹, and wherein one or more hydrogen atoms is optionally replaced by F, Cl, Br, I, CN, or NO₂, an aromatic or heteroaromatic ring system having 5 to 60 aromatic ring atoms optionally substituted by one or more R¹ radicals, an aryloxy, heteroaryloxy, aralkyl, or heteroaralkyl group having 5 to 60 aromatic ring atoms optionally substituted by one or more R¹ radicals, or a diarylamino group, diheteroarylamino group, or arylheteroarylamino group having 10 to 40 aromatic ring atoms optionally substituted by one or more R¹ radicals; and wherein two or more R substituents together optionally define a mono- or polycyclic, aliphatic, aromatic, heteroaromatic and/or benzofused ring system;
R¹ is the same or different in each instance and is H, D, F, Cl, Br, I, N(R²)₂, CN, NO₂, OH, Si(R²)₃, B(OR²)₂, C(═O)R², P(═O)(R²)₂, S(═O)R², S(═O)₂R², OSO₂R², a straight-chain alkyl, alkoxy or thioalkoxy group having 1 to 40 carbon atoms, a branched or cyclic alkyl, alkoxy or thioalkoxy group having 3 to 40 carbon atoms, an alkenyl or alkynyl group having 2 to 40 carbon atoms, each of which is optionally substituted by one or more R² radicals, wherein one or more nonadjacent CH₂ groups are optionally replaced by R²C═CR², C≡C, Si(R²)₂, C═O, C═S, C═NR², P(═O)(R²), SO, SO₂, NR², O, S, or CONR², and wherein one or more hydrogen atoms are optionally replaced by F, Cl, Br, I, CN, or NO₂, an aromatic or heteroaromatic ring system having 5 to 60 aromatic ring atoms, optionally substituted by one or more R² radicals, an aryloxy, heteroaryloxy, aralkyl or heteroaralkyl group having 5 to 60 aromatic ring atoms optionally substituted by one or more R² radicals, or a diarylamino group, diheteroarylamino group or arylheteroarylamino group having 10 to 40 aromatic ring atoms optionally substituted by one or more R² radicals; and wherein two or more R¹ substituents together optionally define a mono- or polycyclic, aliphatic, aromatic, heteroaromatic, and/or benzofused ring system;
R² is the same or different at each instance and is H, D, F or an aliphatic, aromatic and/or heteroaromatic hydrocarbyl radical having 1 to 20 carbon atoms, in which one or more hydrogen atoms may also be replaced by F; two or more R² substituents together may also form a mono- or polycyclic, aliphatic, aromatic, heteroaromatic and/or benzofused ring system; and
wherein if the compound is a charged compound, the compound also comprises one or more counterions, wherein the one or more counterions are the same or different.

16. The compound of claim 15, wherein M is Cu(I).

17. The compound of claim 15, wherein the compound has no electrical charge.

18. The compound of claim 15, wherein the cycle which is formed by A, Y, M and L¹ or L² or L³ has 5, 6, 7, 8, or 9 ring atoms.

19. The compound of claim 18, wherein the cycle which is formed by A, Y, M and L¹ or L² or L³ has 5, 6, 7, or 8 ring atoms.

20. The compound of claim 19, wherein the cycle which is formed by A, Y, M and L¹ or L² or L³ has 5, 6, or 7 ring atoms.

21. The compound of claim 15, wherein L¹ or L² or L³ has 5 to 14 aromatic ring atoms and wherein the aryl and heteroaryl groups are optionally substituted by one or more R radicals.

22. The compound of claim 21, wherein L¹ or L² or L³ has 5 to 13 aromatic ring atoms.

23. The compound of claim 22, wherein L¹ or L² or L³ has 5 to 10 aromatic ring atoms.

24. The compound of claim 15, wherein L¹, L², and L³ are the same or different in each instance and are selected from the group consisting of formulae (2) to (41):
wherein
the groups coordinate to the metal M via the position identified by *;
the position identified by # indicates the position where L¹ or L or L³ is bonded to Y or to A;
X is the same or different in each instance and is CR or N;
D is the same or different in each instance and is OH, O⁻, SH, S⁻, NR₂, NR⁻, PR⁻, PR₂, OR, SR, COO⁻, —C(═O)R, —CR(═NR), or —N(═CR₂).

25. The compound of claim 15, wherein Y is the same or different in each instance a and is a bivalent group selected from CR₂ and O, with the proviso that Y is not O when A ═N.

26. The compound of claim 25, wherein Y is a bivalent group CR₂.

27. The compound of claim 24, wherein:
not more than three X symbols in each group are N;
Y is the same or different in each instance and is a bivalent group selected from CR₂ and O;
n is the same or different in each instance and is 0, 1 or 2.

28. The compound of claim 15, wherein at least two of L¹, L², and L³ are the same and have the same substitution.

29. A process for preparing the compound of claim 15, comprising the step of reacting a metal salt or metal complex of the metal M with the appropriate free ligand, wherein the free ligand is optionally in deprotonated form and wherein the reaction step is optionally followed by a deprotonation step.

30. A formulation comprising at least one compound of claim 15 and at least one further compound.

31. The formulation of claim 30, wherein the at least one further compound is a solvent.

32. An oxygen sensor comprising at least one compound of claim 15.

33. An electronic device comprising at least one compound of claim 15 in at least one layer.

34. The electronic device of claim 33, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells, and organic laser diodes.

35. The electronic device of claim 34, wherein the electronic device is an organic electroluminescent device and wherein the at least one compound is present in an emitting layer as emitter or as matrix or in a hole blocker layer or in an electron transport layer.
